(19) United States
(12) Patent Application Publication
(10) Pub. No.: US 2015/0146342 A1
(43) Pub. Date: May 28, 2015

(54) Multi-Layer Component Having an External Contact and Method for Producing a Multi-Layer Component Having an External Contact

(71) Applicant: EPCOS AG, Muenchen (DE)

(72) Inventor: Markus Weiglhofer, Werndorf (AT)

(21) Appl. No.: 14/405,127

(22) PCT Filed: May 6, 2013
(86) PCT No.: PCT/EP2013/059384

§ 371 Date: Dec. 2, 2014

(30) Foreign Application Priority Data
Jun. 25, 2012 (DE) 10 2012 105 517.3

(51) Int. Cl. H01L 41/047; H01L 41/27; H01L 41/083; H01G 4/30; H01G 4/012

(52) U.S. Cl. CPC H01L 41/0472; H01G 4/30; H01G 4/012; H01L 41/083; H01L 41/27
USPC 361/301.4; 310/364; 427/58; 427/123

(57) ABSTRACT

A multi-layer component has a base body that has a stack made of dielectric layers and internal electrode layers. An external contact is in electrical contact with the electrode layers. The external contact has a first layer and a second layer, where the first layer and the second layer are burned-in.

This patent application is a national phase filing under section 371 of PCT/EP2013/059384, filed May 6, 2013, which claims the priority of German patent application 10 2012 105 517.3, filed Jun. 25, 2012, each of which is incorporated herein by reference in its entirety.

### TECHNICAL FIELD

Embodiments of the present invention relate to a multi-layer component having an external contact and method for producing a multi-layer component having an external contact.

### BACKGROUND

To make contact with a multi-layer component, an external contact of the multi-layer component is soldered to a further contact, for example.

### SUMMARY

The invention provides a multi-layer component having an external contact and also a method for producing a multi-layer component having an external contact. By way of example, the component is a piezo actuator, which can be used to actuate an injection valve in a motor vehicle. Alternatively, the multi-layer component can be, for example, a multi-layer capacitor or a multi-layer varistor. A piezo actuator of multi-layer construction having external electrodes is described, for example, in DE 10 2009 013 125 A1.

In embodiments, a multi-layer component has an improved external contact and also a method for producing an improved external contact of a multi-layer component.

The invention provides a multi-layer component having a main body which has a stack of dielectric layers and internal electrode layers. Moreover, the multi-layer component has an external contact for making electrical contact with the internal electrode layers, wherein the external contact comprises a first layer and a second layer, and wherein the first layer and the second layer are burned in.

The first and the second layer can comprise a metallic material or consist of a metallic material. The first layer preferably comprises copper or consists of copper. Alternatively, the first layer comprises silver-palladium or consists of silver-palladium. The second layer preferably comprises silver or consists of silver. Alternatively, the second layer comprises silver-palladium or consists of silver-palladium.

It is preferable that the dielectric layers and the internal electrode layers are stacked along a stacking direction. The stacking direction preferably corresponds to the longitudinal direction of the main body. It is preferable that the dielectric layers and the internal electrode layers are stacked alternately one on top of another.

It is preferable that the internal electrode layers contain copper or consist of copper. Alternatively, the internal electrode layers contain silver-palladium or consist of silver-palladium.

The dielectric layers can comprise a piezoelectric material. By way of example, the dielectric layers can comprise a ceramic material, in particular a piezoceramic material. To produce the main body, it is possible to use green sheets, to which a metal paste is applied, by way of example, to form internal electrode layers. By way of example, the metal paste is applied in a screen printing process. The metal paste can contain copper. Alternatively, the metal paste can contain silver or silver-palladium. After the metal paste has been applied, the sheets are preferably stacked, pressed and sintered together, so that a monolithic sintered body is formed. It is preferable that the main body of the component is formed by a monolithic sintered body, for example, by a sintered body produced as described above.

By way of example, the multi-layer component is in the form of a piezoelectric component, for example, in the form of a piezo actuator. In the case of a piezo actuator, piezoelectric layers arranged between the internal electrode layers expand when a voltage is applied to the internal electrode layers, such that a stroke of the piezo actuator is generated. The multi-layer component can also be in the form of a different component, for example, in the form of a multi-layer capacitor.

The external contact preferably serves for applying a voltage between internal electrode layers which are adjacent in the stacking direction. By way of example, two external electrodes are arranged on opposing external sides of the main body. It is preferable that in the stacking direction the internal electrode layers are alternately electrically connected to one of the external electrodes and electrically insulated from the other external electrode.

By way of example, the electrode paste is applied in such a way that, as seen in the stacking direction, the electrode layers alternately reach as far as one external side of the stack and are spaced apart from the opposing external side of the stack. In this way, the electrode layers can alternately be electrically connected to one of the external contact.

Alternatively, the multi-layer component can be a fully active multi-layer component. In the case of a fully active multi-layer component, the internal electrode layers extend over the entire cross section of the main body. To alternately connect the internal electrode layers to an external contact, the internal electrode layers are alternately covered on an external side with electrically insulating material. It is preferable that in the stacking direction the internal electrode layers are alternately electrically connected to one of the external electrodes and electrically insulated from the other external electrode.

The external contact preferably has a strip-like form. It is preferable that the external contact extends along the stacking direction of the main body. By way of example, the external contact only partially covers an external side of the main body. Alternatively, the external contact can cover an external side of the main body completely.

The external contact comprises a first layer and a second layer or consists of a first or second layer. The first and the second layer can comprise a metallic material or can consist of a metallic material. The first layer can comprise copper or consist of copper. Alternatively, the first layer can comprise silver-palladium or consist of silver-palladium. The second layer can comprise silver or consist of silver. Alternatively, the second layer can comprise silver-palladium or consist of silver-palladium. By way of example, the external contact comprises a first, copper-containing layer and a second, silver-containing layer or consists of a first, copper-containing layer and a second, silver-containing layer. Alternatively, the external contact can comprise a first layer containing silver-palladium and a second, silver-containing layer or consist of a first layer containing silver-palladium and a second, silver-containing layer. It is preferable that the first layer contains a different material to the second layer.

In a preferred embodiment, the first layer is applied to an external side of the main body by means of screen printing processes. The second layer can likewise be applied to an external side of the main body by means of screen printing processes. The application of a sputtering layer can be dispensed with by the application of an additional screen printing layer to the first layer. This makes it possible to achieve a cost-effective method for applying the external contact.

In a preferred embodiment, the second layer is arranged on the first layer. By way of example, the first layer is in the form of a base layer and the second layer is in the form of a top layer. By way of example, the first layer is covered completely by the second layer. Alternatively, the first layer is only partially covered by the second layer. It is preferable that the first layer is covered by the second layer at least in a region in which there is arranged a soldered joint.

It is preferable that the first layer is optimized in terms of the contact-making of the internal electrode layers. It is preferable that the second layer is optimized in terms of good solderability. Oxide formation can be reduced by the application of a second, for example, silver-containing layer to the first, for example, copper-containing layer. Oxide formation of this nature often arises in the case of copper. If oxide formation is reduced, the solderability is simplified and the reliability of the soldered joint is increased. Furthermore, it is possible to dispense with the use of activating fluxes, which have a negative effect on the reliability of the components and on the service lives of the soldering systems.

In a preferred embodiment, the first layer is arranged in direct contact with the internal electrode layers. By way of example, the first layer is arranged directly on an external surface of the main body. It is preferable that the first layer comprises the same material as the internal electrode layers or consists of the same material as the internal electrode layers. Alternatively, the materials of the first layer and of the internal electrode layers can be different. By way of example, the thermal properties of the internal electrode layers and of the first layer can be matched to one another.

It is preferable that a further contact for making contact with the external contact is present. The further contact is in the form, for example, of a wire harp or of a metal screen.

It is preferable that the further contact is soldered to the external contact. In particular, the further contact is soldered to the second layer.

The invention furthermore provides a method for producing a multi-layer component, wherein an external contact is applied to a main body having a stack of dielectric layers and internal electrode layers, wherein firstly a first layer is applied and then a second layer is applied, and wherein the first layer and the second layer are burned in.

It is preferable that the method is used to produce a multi-layer component as described above.

It is preferable that the first and the second layer comprise a different material or consist of a different material. By way of example, the first layer comprises copper or consists of copper. Alternatively, the first layer comprises silver-palladium or consists of silver-palladium. By way of example, the second layer comprises silver or consists of silver. Alternatively, the second layer comprises silver-palladium or consists of silver-palladium.

It is preferable that the first layer and the second layer are applied by means of screen printing processes.

By way of example, firstly the first layer is applied and burned in and then the second layer is applied and burned in. Alternatively, firstly the first layer is applied and then the second layer is applied. In a further, subsequent step, the two layers are burned in.

### BRIEF DESCRIPTION OF THE DRAWINGS

Hereinbelow, the multi-layer component and the method for producing a multi-layer component will be explained on the basis of schematic figures which are not true to scale and in which:

FIG. 1 shows a side view of a multi-layer component; and

FIG. 2 shows a plan view of a multi-layer component.

### DETAILED DESCRIPTION OF ILLUSTRATIVE EMBODIMENTS

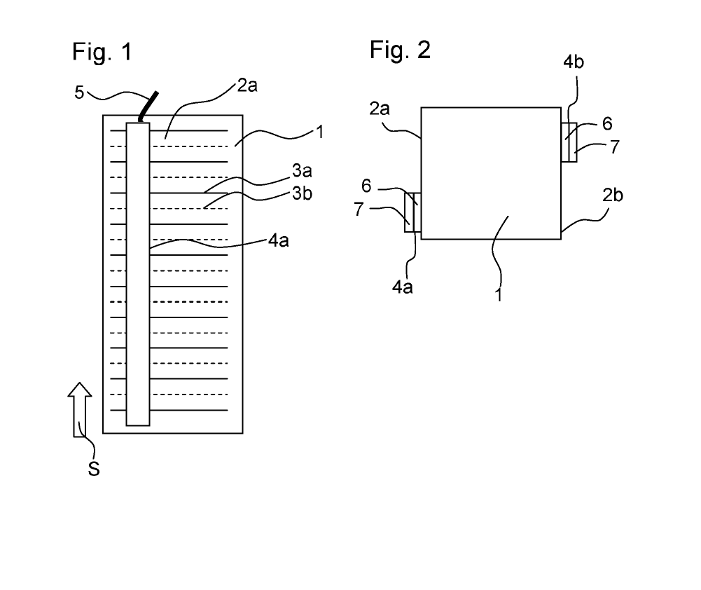

FIG. 1 shows a multi-layer component having a main body 1 with internal electrode layers 3a, 3b and having an external contact 4a in a side view. First internal electrode layers 3a and second internal electrode layers 3b are arranged alternately along a stacking direction S. The internal electrode layers 3b cannot be seen in this side view, but are shown as dashed lines for better understanding. The first internal electrode layers 3a extend as far as a first external side 2a of the main body. The second internal electrode layers 3b extend as far as a second external side 2b of the main body. The arrangement of the external sides 2a and 2b can be seen from FIG. 2. By way of example, the internal electrode layers 3a, 3b comprise copper or consist of copper. Alternatively, the internal electrode layers 3a, 3b comprise silver or silver-palladium or consist of silver or silver-palladium.

The external contact 4a is arranged on the external side 2a of the main body 1. A further external contact 4b is arranged on the opposing external side 2b of the main body 1 (see FIG. 2).

The first external contact 4a is in direct contact with the first internal electrode layers 3a. Analogously, the second external contact 4b is in direct contact with the second internal electrode layers 3b. The external contact 4a, 4b make electrical contact with the internal electrode layers 3a, 3b. The external contact 4a on the external side 2a makes contact with the first internal electrode layers 3a. The external contact 4b on the external side 2b makes contact with the second internal electrode layers 3b (not shown).

A further contact 5 is provided to make electrical contact with the external contact 4a, 4b. The further contact 5 is soldered to the external contact 4a, 4b. The further contact 5 is, for example, a conductive wire. Alternatively, the further contact 5 can be in the form of a wire harp or of a metal screen.

FIG. 2 shows the multi-layer component shown in FIG. 1 in a plan view. It can be seen here that the external contact 4a, 4b consist of in each case two layers. A first, copper-containing layer 6 is arranged in direct contact with the main body 1, in particular with the internal electrode layers 3a, 3b (not shown). A second, silver-containing layer 7 is applied to the copper-containing layer 6. By way of example, the copper-containing layer 6 comprises copper or consists of copper. By way of example, the silver-containing layer 7 comprises silver or consists of silver. A further contact 5 (see FIG. 1) is soldered to the silver-containing layer 7.

The first, copper-containing layer 6 and the second, silver-containing layer 7 are applied by means of screen printing and burned in. By way of example, firstly the copper-containing layer 6 is applied and burned in and subsequently the silver-containing layer 7 is applied and burned in. Alternatively, the copper-containing layer 6 and the silver-containing layer 7 are applied in succession and subsequently burned in together.

1-15. (canceled)

16. A multi-layer component, comprising:
a main body that has a stack of dielectric layers and internal electrode layers; and
an external contact in electrical contact with the internal electrode layers, wherein the external contact comprises a first layer and a second layer, and wherein the first layer and the second layer have physical characteristics resulting from having been burned in.

17. The multi-layer component according to claim 16, wherein the first layer and the second layer are applied by screen printing processes.

18. The multi-layer component according to claim 16, wherein the first layer comprises copper, and wherein the second layer comprises silver.

19. The multi-layer component according to claim 16, wherein the first layer is in direct contact with the electrode layers.

20. The multi-layer component according to claim 16, wherein the second layer is arranged on the first layer.

21. The multi-layer component according to claim 16, further comprising a further contact in electrical contact with the external contact.

22. The multi-layer component according to claim 21, wherein the further contact is soldered to the second layer.

23. The multi-layer component according to claim 16, wherein the external contact has a strip-like form.

24. The multi-layer component according to claim 16, wherein each of the internal electrode layers contain copper.

25. A method for producing an electrical multi-layer component, the method comprising:
applying a first layer to a main body that includes a stack of dielectric layers and internal electrode layers;
applying a second layer over the first layer; and
burning in the first layer and the second layer.

26. The method according to claim 25, wherein the first layer and the second layer are applied by screen printing processes.

27. The method according to claim 25, wherein the second layer is applied directly on the first layer.

28. The method according to claim 25, wherein the first layer is applied and burned in and then the second layer is applied and burned in.

29. The method according to claim 25, wherein the first layer is applied and then the second layer is applied and subsequently the first and second layers are burned in.

30. The method according to claim 25, wherein the first layer comprises copper and wherein the second layer comprises silver.
